(19) United States
(12) Patent Application Publication
(10) Pub. No.: US 2018/0114649 A1
(43) Pub. Date: Apr. 26, 2018

(54) CORROSION-FREE ELECTROLYTE FOR DYE-SENSITIZED SOLAR CELLS

(71) Applicant: City University of Hong Kong, Kowloon (HK)

(72) Inventors: Siu Pang Ng, Kowloon (HK); Chi-man Lawrence Wu, Kowloon (HK); Yu-qiao Fu, Kowloon (HK); Chun Sing Lee, Kowloon (HK)

(21) Appl. No.: 15/333,421

(22) Filed: Oct. 25, 2016

(51) Int. Cl. H01G 9/20; H01L 51/00

(52) U.S. Cl. CPC H01G 9/2018; H01G 9/2013; H01L 51/0086; H01G 9/2059; H01L 51/0067

(57) ABSTRACT

A corrosion-free electrolyte for use in plasmonic-enhanced dye-sensitized solar cells includes ions of a plasmon-supporting metal, in particular iodide anions of the plasmon-supporting metal especially, but not exclusively, gold(I) diiodide anions ([AuI₂]⁻) and/or gold(III) tetraiodide anions ([AuI₄]⁻). Methods for preparing the electrolyte are also disclosed, as are methods for reducing the corrosion of plasmonic structures in plasmonic-enhanced dye-sensitized solar cells and for improving the efficiency of dye-sensitized solar cells, in particular plasmonic-enhanced dye-sensitized solar cells, by disposing the electrolyte between the electrodes. The corrosion-free electrolyte of the present invention provides a corrosion-free environment for the plasmonic structures in the plasmonic-enhanced dye-sensitized solar cells, and further advantageously increases the efficiency of dye-sensitized solar cells, in particular plasmonic-enhanced dye-sensitized solar cells, in the short-circuit current, the open-circuit voltage and the power conversion efficiency.

### TECHNICAL BACKGROUND

The present invention relates to a corrosion-free electrolyte for use in plasmonic-enhanced dye-sensitized solar cells comprising ions of a plasmon-supporting metal, in particular iodide anions of the plasmon-supporting metal especially, but not exclusively, gold(I) diiodide anions ([AuI₂]⁻) and/or gold(III) tetraiodide anions ([AuI₄]⁻). The present invention further provides a method for preparing said electrolyte. Further provided with the present invention are methods for reducing the corrosion of plasmonic structures in plasmonic-enhanced dye-sensitized solar cells and for improving the efficiency of dye-sensitized solar cells, in particular plasmonic-enhanced dye-sensitized solar cells by disposing said electrolyte between the electrodes.

### BACKGROUND OF THE INVENTION

The evolution of the third generation photovoltaics (PVs) with mesoporous solar cells (MSCs) including dye-sensitized solar cells (DSSCs) and perovskite solar cells (PSCs) has helped MSCs to become the most promising alternative to silicon based devices. MSCs provide rival performance compared to traditional silicon PVs at much lower cost. Also, the trapping of light with plasmonic structures in MSCs has been proven as an effective approach to enhance the conversion efficiency even further (Muduli, S. et al., Solar Energy, 2012, 86, 1428-1434, Ding, I. K. et al., Advanced Energy Materials, 2011, 1, 52-57).

DSSCs generally consist of three major components, namely a working electrode as photoanode, electrolyte and counter-electrode. The photoanode usually consists of a transparent conductive oxide window stacked with a compact wide bandgap n-type semiconducting layer and a mesoporous semiconducting layer of the same material and stained by a monolayer of a dye sensitizer. Plasmonic structures in particular nanostructures can be added to the photoanode to enhance light trapping at the mesoporous layer usually of TiO₂. The electrolyte is usually a solution containing iodide ions and triiodide ions from iodide salts and iodine at optimized percentage ratio for electron shuttling by a iodide/triiodide redox couple. The counter-electrode usually consists of a platinized conductive oxide glass, which completes the electrical path of the DSSC in operation. The counter-electrode may be further modified to operate as photocathode, which consists of a p-type semiconducting material and a dye sensitizer monolayer in a similar fashion as the photoanode. Plasmonic enhancement can also be implemented to the photocathode. Thus, a tandem DSSC device is realized as described in U.S. Pat. No. 9,287,057 B2 with plasmon structures in the photocathode and in the photoanode.

However, liquid iodide/triiodide ion containing electrolytes can impact existing plasmonic structures made of plasmon-supporting metals due to the highly corrosive nature of the respective iodine/iodide complexes (Boschloo, G. and Hagfeldt, A., Accounts of Chemical Research, 2009, 42, 1819-1826, Rowley, J. G., The Journal of Physical Chemistry Letters, 2010, 1, 3132-3140). Therefore, existing plasmon-supporting metals, in particular gold and silver are subjected to rapid corrosion once they are in contact with such electrolyte (Brown, M. D., Nano Letters, 2011, 11, 438-445, Du, J. et al., Energy & Environmental Science, 2012, 5, 6914-691, Adhyaksa, G. W. P. et al., ChemSusChem, 2014, 7, 2461-2468, Ding, B. et al., Advanced Energy Materials, 2011, 1, 415-421).

DSSCs with plasmonic structures in particular made of gold and silver outperform conventional DSSCs by enhancing the power conversion efficiency to about 20%. However, special protection is needed to reduce corrosion of these structures by the iodide/triiodide containing electrolyte as mentioned above. Although said corrosion may be alleviated by implementing metal-semiconductor core-shell nanostructures as a protective barrier to the plasmon-supporting metal structures (Jang, Y. H. et al., Nanoscale, 2014, 6, 1823-1832, Ng, S. P. et al., Solar Energy, 2014, 99, 115-125), these semiconductor nanoshells were found to be mesoporous and imperfect so that the electrolyte can infiltrate the nanoshell and attack the nanocore of plasmon-supporting metal (Guan, B. Y. et al., Science Advances, 2016, 2, e1501554, Koktysch, D. et al., Advanced Functional Materials, 2002, 12, 255-265). Thus, the metal nanocores will be eventually dissolved by the corrosive electrolyte. Further, by adding a protective shell of a few nanometers thick, this weakens the plasmonic enhancement, namely the electrical near-field contributing to the electron-hole separation of the dye sensitizer. Therefore, alleviating the corrosive nature of the iodide/triiodide redox couple containing electrolyte and reducing corrosion of the plasmonic structures represents a challenge and prerequisite for the commercial production of plasmonic-enhanced DSSCs. Accordingly, there is a strong need for means and methods for reducing the corrosion of plasmonic structures in plasmonic-enhanced DSSCs.

A number of review articles have been published addressing the photovoltaic mechanism and development of DSSCs. The advancement on each major component of DSSCs was discussed. Hagfeldt et al. (Chemical Reviews, 2010, 110, 6595-6663) published a review on the operational principles, materials development, characterization techniques and modular assembly of the DSSCs. A report on these components was recently updated in 2014 by Ye et al. (Materials Today, 2015, 18, 155-162). The charge transfer mechanism occurring at the TiO₂/dye photoanode was addressed by Ardo and Meyer (Chemical Society Reviews, 2009, 38, 115-164). The work of Wu et al. was dedicated to the advancement of the electrolyte (Chem. Rev., 2015, 115, 2136-2173). The enhancement by plasmonic structures to DSSCs was reviewed recently by Erwin et al. (Energy & Environmental Science, 2016, 9 1577-1601). Moreover, the progress in DSSCs counter-electrode materials was summarized by Thomas et al. (Journal of Materials Chemistry A, 2014, 2, 4474-4490). However, these review articles did not address the corrosive nature of the iodide/triiodide redox couple containing electrolyte on plasmonic structures in plasmonic-enhanced DSSCs by adding plasmon-supporting metals to the electrolyte.

A number of patents and patent applications describe adapted electrolytes for DSSCs such as U.S. Pat. No. 8,299,270 B2, which discloses a clay modified electrolyte, or U.S. Pat. No. 8,455,586 B2, which relates to a copolymer gelator to produce a gel electrolyte for DSSCs. None of them employs plasmon-supporting metals in iodide/triiodide redox couple containing electrolytes for reducing corrosion in plasmonic-enhanced DSSCs.

### SUMMARY OF THE INVENTION

The present invention relates to a novel electrolyte which is corrosion-free and also referenced as corrosion-free electrolyte (further “CFE”) herein especially suitable as electron-shuttling mediator for regenerating oxidized dye-sensitizer molecules to ground state and protecting plasmonic structures from corrosion in plasmonic-enhanced dye-sensitized solar cells (DSSCs), i.e. the electrolyte of the present invention is a multifunctional electrolyte. The advantages thereof will be described with reference to exemplary embodiments in conjunction with the drawings.

The first aspect of the present invention relates to an electrolyte which is corrosion-free for use in plasmonic-enhanced dye-sensitized solar cells (DSSC). Said electrolyte of the present invention comprises:

(i) ions of a plasmon-supporting metal for reducing corrosion of plasmonic structures in the plasmonic-enhanced DSSC, in particular gold(I) diiodide anions ([AuI₂]⁻), gold(III) tetraiodide anions ([AuI₄]⁻) or combinations thereof;
(ii) a redox couple to donate and accept electrons comprising iodide ions and triiodide ions; namely I⁻/I₃⁻ and
(iii) an organic solvent, in particular a polar aprotic solvent such as acetonitrile.

The electrolyte is in particular a liquid.

The plasmon-supporting metal is in particular gold and the source of the ions of the plasmon-supporting metal in the electrolyte is in particular selected from elemental gold or a gold iodide salt such as potassium tetraiodoaurate (KAuI₄) or a mixture of them. The source of the redox couple in the electrolyte of the present invention is iodine and in particular an organic iodide salt selected from the group consisting of 1,2-dimethyl-3-propylimidazolium iodide, 1-methyl-3-propylimidazolium iodide, 3-hexyl-1-methylimidazolium iodide, 3-hexyl-1,2-dimethylimidazolium iodide, 1-ethyl-3-methylimidazolium iodide, 1,3-dimethylimidazolium iodide, 1-butyl-3-methylimidazolium iodide and mixtures thereof.

The present invention provides in another aspect a method of preparing an electrolyte as described above comprising the step of providing a mixture comprising a plasmon-supporting metal containing compound, an organic iodide salt, iodine and an organic solvent. The method of the present invention in particular comprises or consists of the step of adding a plasmon-supporting metal containing compound to a pre-mixture comprising the redox couple and the organic solvent. The pre-mixture can be a commercially available electrolyte for DSSCs such as such as Iodolyte™ like Iodolyte™ AN-50 or obtained comprising adding an organic iodide salt and iodine to the organic solvent. The plasmon-supporting metal containing compound is in particular selected from a metal salt, in particular a metal iodide salt, or the elemental metal of the plasmon-supporting metal or a mixture of both and in particular added to the pre-mixture in an amount of 0.1 wt.-% to 10 wt.-% based on the total weight of the electrolyte.

In another aspect, the present invention provides a plasmonic-enhanced DSSC. Said plasmonic-enhanced DSSC comprises:

a working electrode comprising plasmonic structures for enhancing the electron transfer, in particular embedded in a semiconducting material;
a counter-electrode arranged opposite to the working electrode; and
an electrolyte as described above disposed between the working electrode and the counter-electrode, which electrolyte comprises:
(i) ions of a plasmon-supporting metal for reducing corrosion of the plasmonic structures in the plasmonic-enhanced DSSC;
(ii) a redox couple to donate and accept electrons comprising iodide ions and triiodide ions; and
(iii) an organic solvent.

The plasmon-supporting metal in the plasmonic structures can be selected from gold, silver, copper, aluminium or mixtures thereof. The plasmonic structures are in particular nanostructures such as nanoparticles. The working electrode in particular further comprises an n-type semiconducting material arranged on a transparent conductive substrate, plasmonic structures and a dye sensitizer. The counter-electrode may comprise a p-type semiconducting material arranged on a transparent conductive substrate, plasmonic structures such as plasmonic nanostructures; and a dye sensitizer as photocathode.

Further provided by the present invention is a method of reducing corrosion of plasmonic structures in a plasmonic-enhanced DSSC comprising:

a) providing an electrolyte as described above comprising:
(i) ions of a plasmon-supporting metal;
(ii) a redox couple comprising iodide ions and triiodide ions; and
(iii) an organic solvent; and
b) disposing said electrolyte between a working electrode and a counter-electrode of the plasmonic-enhanced DSSC.

In another aspect, the present invention provides a method of improving the efficiency of a plasmonic-enhanced DSSC comprising:

a) providing an electrolyte as described above comprising:
(i) ions of a plasmon-supporting metal;
(ii) a redox couple comprising iodide ions and iodine; and
(iii) an organic solvent; and
b) disposing said electrolyte between a working electrode and a counter-electrode of the plasmonic-enhanced DSSC.

Improving the efficiency in particular includes improving the short-circuit current density, the open-circuit voltage, the fill factor and overall photovoltaic power conversion efficacy of the plasmonic-enhanced DSSC compared to a plasmonic-enhanced DSSC with an electrolyte provided without ions of a plasmon-supporting metal, i.e. having as redox couple iodide ions and triiodide ions and an organic solvent.

The electrolyte of the present invention is also suitable to be used in DSSCs without plasmonic structures and is able to improve the efficiency of such DSSCs, for example, by deposition of the plasmon-supporting metal, preferably gold in particular in form of nanoislands on the working electrode. Accordingly, the present invention further provides a method of improving the efficiency of a DSSC comprising:

a) providing an electrolyte as described above comprising:
(i) ions of a plasmon-supporting metal;
(ii) a redox couple comprising iodide ions and iodine; and
(iii) an organic solvent; and
b) disposing said electrolyte between a working electrode and a counter-electrode of the DSSC.

The present invention, thus, provides an effective solution to eliminate the corrosion problem of plasmonic structures for plasmonic-enhanced DSSCs. The present invention thereby takes an alternative approach to eliminate the corrosion problem faced by the plasmonic-enhanced DSSCs using iodide/triiodide containing electrolytes, i.e. different from the common surface preservation approach to cap the nanostructures with nanoshells which is associated with several disadvantages as explained above.

In contrast to existing approaches for the plasmonic structures, the present invention introduces ions of a plasmon-supporting metal such as gold(I) diiodide (AuI₂⁻) and gold(III) tetraiodide (AuI₄⁻) anions into an iodide/triiodide electrolyte. Since the redox mechanism of these ions of a plasmon-supporting metal such as gold iodide anions is reversible, the electrolyte is able to release elemental plasmon-supporting metal such as elemental gold and compensate for the loss of plasmon-supporting metal from the plasmonic structures due to iodide/triiodide corrosion and they can be dissolved back into the electrolyte and the plasmonic structures are thereby further protected from free iodide radicals. Thus, the novel electrolyte no longer attacks the embedded plasmonic structures on the working electrode and optionally on the counter-electrode in plasmonic-enhanced DSSCs.

In summary, there are several highly advantageous contributions of the present invention to plasmonic-enhanced DSSCs, in particular: 1) an electrolyte modified by containing ions of a plasmon-supporting metal that electrolyte acts as an electron shuttling medium, 2) an electrolyte modified by containing ions of a plasmon-supporting metal that electrolyte is corrosion-free to embedded plasmonic structures, 3) an electrolyte modified by containing ions of a plasmon-supporting metal that electrolyte releases metallic elements to the working electrode, in particular a mesoporous TiO₂ layer of the photoanode, 4) an electrolyte modified by containing ions of a plasmon-supporting metal that is highly conductive in comparison with a reference electrolyte without ions of a plasmon-supporting metal, 5) an electrolyte modified by containing ions of a plasmon-supporting metal that electrolyte is more positive in standard potential than the reference electrolyte. As a result, the electrolyte of the present invention protects the plasmonic structures, amplifies the short-circuit current, reduces the TiO₂/dye interface impedance and enlarges the open-circuit voltage of the plasmonic-enhanced DSSCs. Thus, the present invention will be essential for the further commercialization of these plasmonic-enhanced DSSCs.

Those of skill in the art will appreciate that the invention described herein is susceptible to variations and modifications other than those specifically described. The invention includes all such variations and modifications. The invention also includes all steps and features referred to or indicated in below, individually or collectively, and any and all combinations of the steps or features.

Other features and aspects of the invention will become apparent by consideration of the following detailed description and accompanying drawings.

### BRIEF DESCRIPTION OF THE DRAWINGS

FIG. 1 shows the cyclic voltammograms of a dummy cell containing a plasmon-supporting metal modified electrolyte obtained by adding gold powder to Iodolyte™ AN-50 in an amount of 0.3 wt.-%, i.e. an electrolyte comprising ions of a plasmon-supporting metal, or a reference electrolyte Iodolyte™ AN-50 that is formed from iodine, 1,2-dimethyl-3-propylimidazolium iodide and acetonitrile without ions of a plasmon-supporting metal.

FIG. 2 is a photovoltaic power conversion datagram of assembled DSSCs containing a plasmon-supporting metal modified electrolyte obtained by adding gold powder to Iodolyte™ AN-50 in an amount of 0.3 wt.-% or the reference electrolyte Iodolyte™ AN-50 that is formed from iodine, 1,2-dimethyl-3-propylimidazolium iodide and acetonitrile without ions of a plasmon-supporting metal.

FIG. 3 is a diagram obtained with electrochemical impedance spectroscopy under AM 1.5 irradiation of the assembled DSSCs containing a plasmon-supporting metal modified electrolyte obtained by adding gold powder to Iodolyte™ AN-50 in an amount of 0.3 wt.-% or the reference electrolyte Iodolyte™ AN-50 that is formed from iodine, 1,2-dimethyl-3-propylimidazolium iodide and acetonitrile without ions of a plasmon-supporting metal.

FIG. 4 is the statistical histogram of the amount of elemental gold as plasmon-supporting metal containing compound in weight percentage added to Iodolyte™ AN-50 as pre-mixture and the obtained photovoltaic power conversion efficiency.

FIG. 5A is a field-emission scanning electron micrograph of the reference mesoporous TiO₂ photoanode.

FIG. 5B is a field-emission scanning electron micrograph of metallic gold nanoislands deposited on the mesoporous TiO₂ photoanode.

FIG. 5C is a diagram obtained with X-ray photoelectron spectroscopy of the reference mesoporous TiO₂ photoanode to determine the work function at the TiO₂ interface.

FIG. 5D is a diagram obtained with X-ray photoelectron spectroscopy of the mesoporous TiO₂ photoanode with gold nanoislands deposition to determine the work function at the modified TiO₂/nanogold interface.

FIG. 6 shows the standard potential (against Ag/AgCl reference electrode) of the electrolyte containing ions of the plasmon-supporting metal which is gold and those of the Iodolyte™ AN-50 that is formed with iodine, 1,2-dimethyl-3-propylimidazolium iodide and acetonitrile without ions of a plasmon-supporting metal.

FIG. 7 illustrates the retardation of electron recombination by the Schottky barrier (SB) and the increased V_{oc}. A metal-semiconductor heterojunction is formed with the elemental gold deposited on the mesoporous TiO₂ photoanode. As the work function of anatase TiO₂ is about 4.2 eV whereas that of gold nanoparticle is about 5.35 to 5.76 eV, there is upward bending of the TiO₂ conduction band (CB) and formation of a SB.

### DETAILED DESCRIPTION OF THE INVENTION

Unless otherwise defined, all technical terms used herein have the same meaning as commonly understood by one skilled in the art to which the invention belongs.

As used herein, “comprising” means including the following elements but not excluding others. “Essentially consisting of” means that the material consists of the respective element along with usually and unavoidable impurities such as side products and components usually resulting from the respective preparation or method for obtaining the material such as traces of further components or solvents. The expression that a material like a solvent “is” certain material as used herein means that the material essentially consists of said specific material. As used herein, the forms “a,” “an,” and “the,” are intended to include the singular and plural forms unless the context clearly indicates otherwise. The expression “arranged on a material” is to be interpreted broadly as used here and covers both an arrangement directly onto said material and also an arrangement wherein some further material is in between.

The present invention provides an electrolyte for use in a plasmonic-enhanced dye-sensitized solar cell (DSSC). Plasmonic-enhanced DSSCs and their construction are known to one of skill in the art. They are known as dye-sensitized solar cells able to convert light energy into electricity while making use of photosensitive dyes which dye-sensitized solar cells further comprise plasmonic structures of a plasmon-supporting material, in particular in form of nanostructures such as nanoparticles for example embedded in an n-type semiconducting material of the working electrode, i.e. photoanode. The plasmonic-enhanced DSSC can be a plasmonic-enhanced tandem DSSC with plasmonic structures embedded in both, the working electrode and the counter-electrode, in particular embedded in semiconducting materials of the photoanode and of the photocathode. Nanostructures such as nanoparticles are generally structures such as particles having an average diameter of less than 1000 nm, in particular less than 100 nm as further explained below.

Said electrolyte of the present invention comprises:

(i) ions of a plasmon-supporting metal for reducing corrosion of plasmonic structures in the plasmonic-enhanced DSSC;
(ii) a redox couple to donate and accept electrons comprising iodide ions and triiodide ions; namely I⁻/I₃⁻ and
(iii) an organic solvent.

An “electrolyte” is generally an electric conductor comprising a redox couple able to transport an electric current via long-range motion of ions such as a iodide/triiodide redox couple, i.e. it includes free ions that make it electrically conductive by the motion of free ions. I.e. the term “electrolyte” used herein means an electrically conductive medium which performs electron shuttling between the working electrode, i.e. the photoanode, and the counter-electrode of a DSSC.

The electrolyte is preferably a liquid, i.e. is a liquid at room temperature, namely molten at a temperature of about 25±2° C. and the usual working temperature of DSSCs, or solid or semi-solid. Preferably the electrolyte of the present invention is liquid allowing for an excellent penetration and a fast diffusion rate.

“Plasmon-supporting metals” are metals that are able to improve the efficiency and light trapping of a DSSC, namely they can enhance the electron and hole carrier transfer in a DSSC, in particular they can enhance light trapping at a mesoporous layer of the electrode and induce an electrical near-field contributing to the electron-hole separation of the dye sensitizer.

More specifically, plasmon-supporting metals are metals that support surface plasmons in a DSSC. Incoming light at the plasmon resonance frequency induces surface plasmons, i.e. electron oscillations at the surface of the plasmon-supporting metal. Said collective oscillation of free electrons confined at the surface of the plasmon-supporting metals induced when the frequency of incident light matches the plasmon frequency of the irradiated metal results in substantially enhanced electric fields which can facilitate both light absorption and charge separation.

For use in DSSCs, plasmon-supporting metals need to be characterized by low losses due to inter-band transitions in the optional region as this would otherwise damp the plasmonic resonance and the plasmonic enhancement could not be reached, by a sufficient chemical stability and low reactivity such as with water and air. Metals providing such properties are in particular noble metals, more specifically metals such as gold, silver, copper and aluminium. They avoid inter-band transitions in a sufficient part of the optical spectrum and are sufficiently stable to be used in DSSCs.

The source of the ions of the plasmon-supporting metal in the electrolyte of the present invention is in particular elemental plasmon-supporting metal, a plasmon-supporting metal salt such as a metal iodide salt or both of them, in particular the elemental metal or a iodide salt of the plasmon-supporting metal. In most preferred embodiments, the source of the ions of the plasmon-supporting metal is selected from elemental gold or potassium tetraiodoaurate or a mixture of them.

The source of the redox couple in the electrolyte of the present invention is iodine and preferably an organic iodide salt. The organic iodide salt is preferably selected from the group consisting of 1,2-dimethyl-3-propylimidazolium iodide, 1-methyl-3-propylimidazolium iodide, 3-hexyl-1-methylimidazolium iodide, 3-hexyl-1,2-dimethylimidazolium iodide, 1-ethyl-3-methylimidazolium iodide, 1,3-dimethylimidazolium iodide, 1-butyl-3-methylimidazolium iodide and mixtures thereof.

The organic solvent is an organic solvent able to facilitate the reversible deposition and dissolution of plasmon-supporting metal in the iodide/triiodide environment. The organic solvent is in particular a polar aprotic solvent. A polar aprotic solvent means a polar solvent lacking an easily removable proton that is a liquid at room temperature, i.e. liquid at about a temperature of 25±2° C. The term “polar” indicates that it is more polar than other solvents, in particular due to polar functional groups, and that the solvent usually has a dielectric constant equal to or greater than about 5, in particular equal to or greater than about 15. Non-binding examples of polar aprotic solvents include acetonitrile, dichloromethane, tetrahydrofuran, ethyl acetate, N,N-dimethylformamide, dimethyl sulfoxide, acetone, hexamethylphosphoric triamide, propylene carbonate or mixtures thereof.

The organic solvent is preferably selected from the group consisting of acetonitrile, dichloromethane, tetrahydrofuran, ethyl acetate, N,N-dimethylformamide, dimethyl sulfoxide, acetone, hexamethylphosphoric triamide, propylene carbonate and mixtures thereof.

In embodiments of the present invention, the organic solvent is a mixture of propylene carbonate and acetonitrile, in particular with about 25 wt.-% to about 75 wt.-% of propylene carbonate based on the weight of the organic solvent such as 25 wt.-%, 50 wt.-% or 75 wt.-%. In alternative embodiments of the present invention, the organic solvent is a mixture of acetonitrile and N,N-dimethylformamide in particular with about 25 wt.-% to about 75 wt.-% of acetonitrile based on the weight of the organic solvent such as 25 wt.-%, 50 wt.-% or 75 wt.-%. In alternative embodiments of the present invention, the organic solvent is a mixture of propylene carbonate and N,N-dimethylformamide with about 25 wt.-% to about 75 wt.-% of propylene carbonate based on the weight of the organic solvent such as 25 wt.-%, 50 wt.-% or 75 wt.-%.

In preferred embodiments of the present invention, the organic solvent comprises and further preferred is acetonitrile.

The plasmon-supporting metal is in embodiments of the present invention selected from one or more noble metals. In preferred embodiments of the present invention, the plasmon-supporting metal is selected from the group consisting of gold, silver, copper and aluminum or combinations thereof. Further preferred, the plasmon-supporting metal is selected from the group consisting of gold, silver or combinations thereof.

The electrolyte in particular comprises iodide anions of the plasmon-supporting metal, i.e. the ions of the plasmon-supporting metal are preferably iodide anions of the plasmon-supporting metal.

The ions of the plasmon-supporting metal are most preferably selected from gold(I) diiodide anions ([AuI₂]⁻), tetraiodide anions ([AuI₄]⁻) or combinations thereof, in particular combinations thereof.

The electrolyte of the present invention is preferably obtained by steps comprising preparing a mixture comprising a plasmon-supporting metal containing compound, an organic iodide salt, iodine and an organic solvent. Preferably, the electrolyte is obtained by adding a plasmon-supporting metal containing compound to a pre-mixture comprising the redox couple and the organic solvent. The pre-mixture is preferably obtained comprising adding an organic iodide salt and iodine to the organic solvent, for example it is obtained by adding the organic iodide salt and iodine to the organic solvent.

The plasmon-supporting metal containing compound is a compound which is able to release the plasmon-supporting metal or ions thereof such that ions of the plasmon-supporting metal can be formed in the mixture through a reaction with iodide/triiodide ions and iodine, respectively, in particular in the pre-mixture. The plasmon-supporting metal containing compound is preferably selected from a metal salt such as a metal iodide salt or the elemental metal or both of them of the plasmon-supporting metal. A metal salt of the plasmon-supporting metal such as a metal iodide salt is in particular able to release ions of the plasmon-supporting metal such as metal iodide anions which react with iodine to reduce and more preferably prevent corrosion of the plasmonic structures embedded in the photoanode and photocathode of the plasmonic-enhanced DSSC. An elemental metal, i.e. elemental plasmon-supporting metal, is in particular able to react with iodide to produce ions of the plasmon-supporting metal such as metal iodide anions which react with iodine to reduce and more preferably prevent corrosion of the plasmonic structures embedded in the photoanode and photocathode of the plasmonic-enhanced DSSC.

Preferably, the plasmon-supporting metal containing compound is selected from a metal salt, i.e. a plasmon-supporting metal salt, or the elemental metal, i.e. the elemental plasmon-supporting metal, or a mixture of both is added to the pre-mixture in an amount of about 0.1 wt.-% to about 10 wt.-% based on the total weight of the electrolyte. The metal salt can be, for example, selected from the group consisting of a gold(III) iodide, a silver(I) iodide, a copper(I) iodide, an aluminum(III) iodide or mixtures thereof. The plasmon-supporting metal containing compound is most preferably selected from the group consisting of elemental gold, potassium tetraiodoaurate (KAuI₄) or mixtures thereof.

The pre-mixture can be a commercially available electrolyte for DSSCs such as Iodolyte™ like Iodolyte™ AN-50. I.e. in embodiments of the present invention, the electrolyte of the present invention is obtained by adding the plasmon-supporting metal containing compound to a commercially available electrolyte for DSSCs such as Iodolyte™ like Iodolyte™ AN-50.

The organic iodide salt is an organic iodide salt able to release iodide ions for the redox couple and is preferably selected from the group consisting of 1,2-dimethyl-3-propylimidazolium iodide, 1-methyl-3-propylimidazolium iodide, 3-hexyl-1-methylimidazolium iodide, 3-hexyl-1,2-dimethylimidazolium iodide, 1-ethyl-3-methylimidazolium iodide, 1,3-dimethylimidazolium iodide, 1-butyl-3-methylimidazolium iodide and mixtures thereof.

The iodine is able to react with the iodide ions released from the organic iodide salt to form triiodide ions.

The electrolyte of the present invention is in preferred embodiments of the present invention obtained by adding potassium tetraiodoaurate as plasmon-supporting metal containing compound to a pre-mixture obtained by steps comprising adding 1,2-dimethyl-3-propylimidazolium iodide as organic iodide salt and iodine to acetonitrile as organic solvent. The pre-mixture can be obtained by adding 1,2-dimethyl-3-propylimidazolium iodide as organic iodide salt and iodine to acetonitrile as organic solvent.

Preferably, plasmon-supporting metal, organic iodide salt, iodine and acetonitrile are used in the following amounts based on the total weight of the electrolyte:

about 0.2 wt.-% to about 4.8 wt.-% potassium tetraiodoaurate, further preferred about 1.2 wt.-%;
at least about 50 wt.-% of acetonitrile;
about 10 wt.-% to about 25 wt.-% 1,2-dimethyl-3-propylimidazolium iodide; and
about 2.5 wt.-% to about 10 wt.-% iodine.

The electrolyte of the present invention is in alternative preferred embodiments of the present invention obtained by adding elemental gold as plasmon-supporting metal containing compound to a pre-mixture obtained by steps comprising adding 1,2-dimethyl-3-propylimidazolium iodide as organic iodide salt and iodine to acetonitrile as organic solvent. The pre-mixture can be obtained by adding 1,2-dimethyl-3-propylimidazolium iodide as organic iodide salt and iodine to acetonitrile as organic solvent.

Preferably, plasmon-supporting metal, organic iodide salt, iodine and acetonitrile are used in the following amounts based on the total weight of the electrolyte:

about 0.05 wt.-% to about 1.5 wt.-% elemental gold, preferably about 0.05 wt.-% to about 1.2 wt.-%, further preferably about 0.3 wt.-% elemental gold;
at least about 50 wt.-% of acetonitrile;
about 10 wt.-% to about 25 wt.-% 1,2-dimethyl-3-propylimidazolium iodide; and
about 2.5 wt.-% to about 10 wt.-% iodine.

The electrolyte of the present invention is in alternative preferred embodiments of the present invention obtained by adding a plasmon-supporting metal containing compound selected from the group consisting of a silver(I) iodide, a copper(I) iodide, an aluminum(III) iodide or mixtures thereof to the pre-mixture. The total amount of said plasmon-supporting metal containing compound used is preferably about 0.1 wt.-% to about 10 wt.-% based on the total weight of the electrolyte.

The term “corrosion-free” used herein means that plasmonic structures of a plasmon-supporting metal such as of gold or silver are not subject to significant corrosion when using the electrolyte of the present invention, i.e. the corrosion of the plasmonic structures in the plasmonic-enhanced DSSC is reduced and further preferred prevented, in particular significantly reduced and most preferably there is no corrosion of plasmonic structures in the plasmonic-enhanced DSSC measurable over the usual time and conditions of use of a plasmonic-enhanced DSSC, i.e. corrosion is prevented. In particular, the electrolyte is able to release elemental plasmon-supporting metal such as elemental gold too, thus, compensate for the loss of plasmon-supporting metal of the plasmonic structures via iodide/triiodide corrosion, which can dissolved back at equilibrium so that said iodide/triiodide couples are consumed to form ions of the plasmon-supporting metal such as gold iodide anions and cannot corrode the plasmonic structures.

In particular, the electrolyte is able to release elemental gold such that it is deposited on the working electrode, i.e. photoanode, in particular on mesoporous semiconducting material such as mesoporous TiO₂ comprising TiO₂ nanoparticles. The term “mesoporous” refers to a porous material having pores with an average diameter of about 2 nm to 50 nm. Nanoparticles are generally particles with an average diameter below 1000 nm. In particular the TiO₂ nanoparticles have an average diameter below 100 nm. The elemental plasmon-supporting metal in particular elemental gold is in particular deposited in form of nanoislands, in particular gold nanoislands on the TiO₂ nanoparticles. The average diameter of these nanoislands is preferably below 100 nm, in particular about 30 nm to about 60 nm.

“Diameter” as used herein preferably refers to the Feret (or Feret's) diameter at the thickest point of such structure, particle or island or pore. The Feret diameter is a measure of an object size along a specified direction and can be defined as the distance between the two parallel planes restricting the object perpendicular to that direction. The Feret diameter can be determined, for example, with microscopic methods. I.e. if the Feret diameters measured for the different directions of the structure, particle or island or pore differ, the “diameter” referred to in the present patent application always refers to the highest value measured. “Average diameter” refers to the average of “diameter” preferably measured with at least 10 structures, particles or islands. Particles are generally structures substantially having a spherical form.

Thus, the electrolyte of the present invention allows for a significant reduction of the corrosion of plasmonic structures in plasmonic-enhanced DSSCs. Further, the electrolyte of the present invention allows for improving one or more of the short-circuit current density, open-circuit voltage, fill factor and/or overall photovoltaic power conversion efficacy of the DSSC compared to a DSSC with an electrolyte provided without ions of a plasmon-supporting metal having as redox couple iodide/triiodide and an organic solvent.

In particular, all of short-circuit current density, open-circuit voltage, fill factor and overall photovoltaic power conversion efficacy of the DSSC are improved, namely increased. In particular, the electrolyte allows for a short-circuit current density of a DSSC of at least 8 mA/cm², in particular at least 9 mA/cm² and more preferably at least about 10 mA/cm². The open-circuit voltage of a DSSC with the electrolyte of the present invention is preferably at least 0.65 V. The overall photovoltaic power conversion efficacy (PCE) of the DSSC with the electrolyte of the present invention is in particular at least 3.5%, further preferred at least 4%. The PCE is in particular increased by at least 100% compared to the use of an electrolyte provided without ions of a plasmon-supporting metal having as redox couple iodide/triiodide and an organic solvent.

The present invention provides in another aspect a method of preparing an electrolyte as described above comprising:

(i) ions of a plasmon-supporting metal for reducing corrosion of plasmonic structures in the plasmonic-enhanced DSSC;
(ii) a redox couple to donate and accept electrons comprising iodide ions and triiodide ions; namely I⁻/I₃⁻ and
(iii) an organic solvent.

Said method comprises the step of providing a mixture comprising a plasmon-supporting metal containing compound, an organic iodide salt, iodine and an organic solvent. The method of the present invention preferably comprises and in particular consists of the step of adding a plasmon-supporting metal containing compound to a pre-mixture comprising the redox couple and the organic solvent. The pre-mixture can be a commercially available electrolyte for DSSCs such as Iodolyte™ like Iodolyte™ AN-50. I.e. in embodiments of the present invention, the method of the present invention comprises and in particular consists of the step of adding the plasmon-supporting metal containing compound to a commercially available electrolyte for DSSCs such as Iodolyte™ like Iodolyte™ AN-50.

The plasmon-supporting metal containing compound is preferably selected from a metal salt, i.e a plasmon-supporting metal salt, or the elemental plasmon-supporting metal or both of them. The plasmon-supporting metal containing compound is in particular embodiments selected from the group consisting of elemental gold or potassium tetraiodoaurate or mixtures thereof.

In alternative embodiments of the present invention, the method comprises steps of:

a) providing a pre-mixture comprising adding an organic iodide salt and iodine to the organic solvent; and
b) adding a plasmon-supporting metal containing compound to the pre-mixture of step a).

Step a) may consist of the step of adding the organic iodide salt and iodine to the organic solvent. Preferably, the method consists of steps a) and b).

The organic iodide salt is preferably selected from the group consisting of 1,2-dimethyl-3-propylimidazolium iodide, 1-methyl-3-propylimidazolium iodide, 3-hexyl-1-methylimidazolium iodide, 3-hexyl-1,2-dimethylimidazolium iodide, 1-ethyl-3-methylimidazolium iodide, 1,3-dimethylimidazolium iodide, 1-butyl-3-methylimidazolium iodide and mixtures thereof.

The method of the present invention in embodiments comprises the step of proving a pre-mixture comprising or for example consisting of adding 1,2-dimethyl-3-propylimidazolium iodide and iodine to acetonitrile and adding potassium tetraiodoaurate to the pre-mixture, wherein 1,2-dimethyl-3-propylimidazolium iodide, iodine, acetonitrile and potassium tetraiodoaurate are used in the following amounts based on the total weight of the electrolyte:

about 0.2 wt.-% to about 4.8 wt.-% potassium tetraiodoaurate, further preferred about 1.2 wt.-%;
at least about 50 wt.-% of acetonitrile;
about 10 wt.-% to about 25 wt.-% 1,2-dimethyl-3-propylimidazolium iodide; and
about 2.5 wt.-% to about 10 wt.-% iodine.

The method of the present invention in alternative embodiments comprises the step of proving a pre-mixture comprising adding 1,2-dimethyl-3-propylimidazolium iodide and iodine to acetonitrile and adding elemental gold to the pre-mixture, wherein 1,2-dimethyl-3-propylimidazolium iodide, iodine, acetonitrile and elemental gold are used in the following amounts based on the total weight of the electrolyte:

about 0.05 wt.-% to about 1.5 wt.-% elemental gold, preferably about 0.05 wt.-% to about 1.2 wt.-%, more preferably about 0.3 wt.-% elemental gold;
at least about 50 wt.-% of acetonitrile;
about 10 wt.-% to about 25 wt.-% 1,2-dimethyl-3-propylimidazolium iodide; and
about 2.5 wt.-% to about 10 wt.-% iodine.

Elemental gold is preferably used in form of gold powder which is commercially available. The gold powder used preferably has particle sizes with an average diameter of less than about 10 μm. The purity of the gold powder is preferably at least about 99% (w/w), more preferably at least about 99.9% (w/w). I.e. the impurity content is preferably at most about 1% (w/w), further preferred at most about 0.1% (w/w).

The method of the present invention in alternative embodiments comprises adding one or more of a silver(I) iodide, a copper(I) iodide and an aluminum(III) iodide as plasmon-supporting metal containing compound to the pre-mixture with a total amount of about 0.1 wt.-% to about 10 wt.-% based on the total weight of the electrolyte.

In another aspect, the present invention provides a plasmonic-enhanced DSSC. Said plasmonic-enhanced DSSC comprises:

a working electrode comprising plasmonic structures for enhancing the electron transfer;
a counter-electrode arranged opposite to the working electrode; and
an electrolyte as described above disposed between the working electrode and the counter-electrode, which electrolyte comprises:
(i) ions of a plasmon-supporting metal for reducing corrosion of the plasmonic structures in the plasmonic-enhanced DSSC;
(ii) a redox couple to donate and accept electrons comprising iodide ions and triiodide ions; and
(iii) an organic solvent.

The plasmonic structures are structures comprising a plasmon-supporting metal usually embedded in a semiconducting material or arranged on the surface of the semiconducting material. The plasmon-supporting metal in the plasmonic structures can be selected from gold, silver, copper, aluminium or mixtures thereof, in particular it is gold. The plasmonic structures are in particular nanostructures such as nanoparticles with an average diameter below 1000 nm, in particular between 10 nm and 100 nm. The ions of the plasmon-supporting metal in the electrolyte are preferably selected from the group consisting of gold(I) diiodide anions, gold(III) tetraiodide anions and mixtures thereof.

The working electrode further preferred comprises an n-type semiconducting material arranged on a transparent conductive substrate, plasmonic structures and a dye sensitizer. Respective materials as well as methods for preparing the working electrode are well known to one of skill in the art including sintering, vacuum thermal evaporation and the like. The n-type semiconducting material is in particular TiO₂ present in form of one or more layers including a mesoporous layer in particular of TiO₂ nanoparticles, which forms a highly porous structure with a high surface area. TiO₂ can be present in the anatase structure.

The dye sensitizer can be, for example, a ruthenium-based organic dye in form of a monolayer applied on the n-type semiconducting material such as N-719 dye sensitizer. The plasmonic structures of the working electrode, i.e. the photoanode, are preferably plasmonic nanostructures embedded in the n-type semiconducting material with an average diameter of less than 100 nm.

The counter-electrode can comprise a platinized conductive substrate. The counter-electrode may in embodiments of the present invention comprise a p-type semiconducting material arranged on a transparent conductive substrate, plasmonic structures such as nanostructures; and a dye sensitizer as photocathode. I.e. in embodiments of the present invention, the plasmonic-enhanced DSSC is a tandem plasmonic-enhanced DSSC.

The transparent conductive substrate can comprise glass or plastic and can be a glass coated with rare-earth metal doped oxide such as indium-doped tin oxide (ITO) or fluorine-doped tin oxide (FTO). The person of skill in the art is aware of such materials and how to prepare them. The term “transparent” means capable of transmitting visible light without appreciable scattering or absorption in the visible region. “Visible light” or “visible region” is generally referenced as portion of the electromagnetic spectrum that is visible to the human eye, namely electromagnetic radiation having wavelengths from about 380 to 800 nm.

Further provided by the present invention is a method of reducing corrosion of plasmonic structures in a plasmonic-enhanced DSSC comprising:

a) providing an electrolyte as described above comprising:
(i) ions of a plasmon-supporting metal;
(ii) a redox couple to donate and accept electrons comprising iodide ions and triiodide ions; and
(iii) an organic solvent; and
b) disposing said electrolyte between a working electrode and a counter-electrode of the plasmonic-enhanced DSSC.

Step a) preferably comprises and in particular consists of the step of adding a plasmon-supporting metal containing compound to a pre-mixture comprising the redox couple and the organic solvent as described above. The pre-mixture can be a commercially available electrolyte for DSSCs such as Iodolyte™ like Iodolyte™ AN-50. Alternatively, step a) comprises steps of providing a pre-mixture comprising adding an organic iodide salt and iodine to the organic solvent; and adding a plasmon-supporting metal containing compound to the pre-mixture as described above.

For example, step b) may be carried out by injecting the electrolyte through an injection hole in the counter-electrode.

The plasmon-supporting metal is preferably selected from the group consisting of gold, silver copper, aluminum or mixtures thereof, in particular the plasmon-supporting metal is selected from gold, silver or mixtures thereof, most preferably it is gold. The ions of the plasmon-supporting metal are most preferably selected from gold(I) diiodide anions ([AuI₂]⁻), gold(III) tetraiodide anions ([AuI₄]⁻) or mixtures thereof, in particular mixtures thereof.

In another aspect, the present invention provides a method of improving the efficiency of a plasmonic-enhanced DSSC comprising:

a) providing an electrolyte as described above comprising:
(i) ions of a plasmon-supporting metal;
(ii) a redox couple to donate and accept electrons comprising iodide ions and triiodide ions; and
(iii) an organic solvent; and
b) disposing said electrolyte between a working electrode and a counter-electrode of the plasmonic-enhanced DSSC.

Step a) preferably comprises and in particular consists of the step of adding a plasmon-supporting metal containing compound to a pre-mixture comprising the redox couple and the organic solvent as described above. The pre-mixture can be a commercially available electrolyte for DSSCs such as Iodolyte™ like Iodolyte™ AN-50. Alternatively, step a) comprises steps of providing a pre-mixture comprising adding an organic iodide salt and iodine to the organic solvent; and adding a plasmon-supporting metal containing compound to the pre-mixture as described above.

For example, step b) may be carried out by injecting the electrolyte through an injection hole in the counter-electrode.

The plasmon-supporting metal is preferably selected from the group consisting of gold, silver copper, aluminum or mixtures thereof, in particular the plasmon-supporting metal is selected from gold, silver or mixtures thereof, most preferably it is gold. The ions of the plasmon-supporting metal are most preferably selected from gold(I) diiodide anions ([AuI₂]⁻), gold(III) tetraiodide anions ([AuI₄]⁻) or mixtures thereof, in particular combinations thereof.

In particular, “improving the efficiency” includes one or more of improving the short-circuit current density, the open-circuit voltage, the fill factor and/or the overall photovoltaic power conversion efficacy of the plasmonic-enhanced DSSC compared to a plasmonic-enhanced DSSC with an electrolyte provided without ions of a plasmon-supporting metal having as redox couple iodide ions and triiodide ions and an organic solvent.

In particular, the short-circuit current density of the plasmonic-enhanced DSSC is at least 8 mA/cm², in particular at least 9 mA/cm² and more preferably at least about 10 mA/cm². The open-circuit voltage of the plasmonic-enhanced DSSC is preferably at least 0.65 V. The overall photovoltaic power conversion efficacy (PCE) of the plasmonic-enhanced DSSC is in particular at least 3.5%, further preferred at least 4%. The PCE is in particular increased by at least 100% compared to a plasmonic-enhanced DSSC with an electrolyte provided without ions of a plasmon-supporting metal having as redox couple iodide ions and triiodide ions and an organic solvent.

Improving the short-circuit current density of the plasmonic-enhanced DSSC in particular includes a deposition of the plasmon-supporting metal, preferably gold in particular in form of nanoislands on the electrode(s) in particular on a mesoporous TiO₂ layer from the electrolyte thereby increasing the plasmonic enhancement effect such as boosting the photo-electron injection efficiency of the dye-sensitizer

Improving the open-circuit voltage of the plasmonic-enhanced DSSC includes in particular a deposition of the plasmon-supporting metal, preferably gold in particular in form of nanoislands on the electrode(s) in particular on a mesoporous TiO₂ layer and thereby creating a Schottky barrier that increases the conduction band edge of TiO₂ like anatase TiO₂ nanoparticles.

Increasing the open-circuit voltage of the plasmonic-enhanced DSSC further includes shifting the standard electrode potential of the redox reaction towards positive with the electrolyte of the present invention.

Still further, the electrolyte of the present invention leads to a reduction of the semiconducting material like TiO₂/dye sensitizer/electrolyte interface impedance including a deposition of the plasmon-supporting metal, preferably gold in particular in form of nanoislands on the electrode(s) in particular on a mesoporous TiO₂ layer and thereby creating a Schottky barrier that retards the recombination of the injected electron with the oxidized dye-sensitizers and iodide/triiodide redox couple.

The person of skill in the art will recognize that the electrolyte of the present invention is also suitable to be used in DSSCs without plasmonic structures and is able to improve the efficiency of such DSSCs, for example, by deposition of plasmon-supporting metal, preferably gold in particular in form of nanoislands on the electrode(s) in particular on a mesoporous TiO₂ layer from the electrolyte thereby providing a plasmonic enhancement effect such as boosting the photo-electron injection efficiency of the dye-sensitizer. Accordingly, the present invention further provides a method of improving the efficiency of a DSSC comprising:

a) providing an electrolyte as described above comprising:
(i) ions of a plasmon-supporting metal;
(ii) a redox couple to donate and accept electrons comprising iodide ions and triiodide ions; and
(iii) an organic solvent; and
b) disposing said electrolyte between a working electrode and a counter-electrode of the DSSC.

Step a) preferably comprises and in particular consists of the step of adding a plasmon-supporting metal containing compound to a pre-mixture comprising the redox couple and the organic solvent as described above. The pre-mixture can be a commercially available electrolyte for DSSCs such as Iodolyte™ like Iodolyte™ AN-50. Alternatively, step a) comprises steps of providing a pre-mixture comprising adding an organic iodide salt and iodine to the organic solvent; and adding a plasmon-supporting metal containing compound to the pre-mixture as described above.

The improvement in the efficacy can be one or more of improving the short-circuit current density, the open-circuit voltage, the fill factor and/or overall photovoltaic power conversion efficacy of the DSSC compared to a DSSC with an electrolyte provided without ions of a plasmon-supporting metal having as redox couple iodide ions and triiodide ions and an organic solvent.

### EXAMPLES

As reference electrolyte in the following examples, Iodolyte™ AN-50 (safety data sheet, Solaronix SA, revision 05.06.2012, version number 1) formed from acetonitrile 50% to 100 wt.-%, 1,2-dimethyl-3-propylimidazolium iodide 10% to 25% wt.-%, and iodine 2.5% to 10% wt.-%. The corrosion-free electrolyte (CFE) of the present invention used in the following examples has the same solvent and solutes, i.e is formed by 1,2-dimethyl-3-propylimidazolium iodide, iodine and acetonitrile, wherein additionally a plasmon-supporting metal containing compound is added which is potassium tetraiodoaurate (KAuI₄) or gold powder.

### Example 1

### Conductivity of a Corrosion-Free Electrolyte of the Present Invention

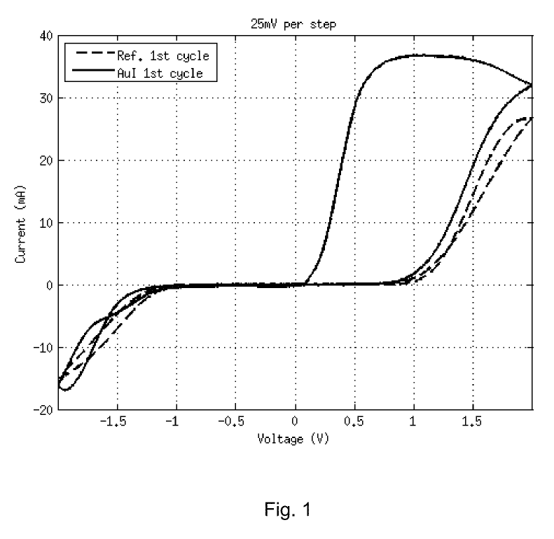

To demonstrate the improved conductivity of the corrosion-free electrolyte (CFE), 2 dummy cells made of transparent conductive oxide glass as the electrodes were assembled with the reference (i.e. Iodolyte™ AN-50) and the CFE (Iodolyte™ AN-50 with gold powder added in an amount of 0.3 wt.-% based on the total weight of the electrolyte) filled in between the electrodes respectively. The cell dimension was 6 mm square and identical to the DSSC device. Cyclic voltammetry was performed by applying potential differences from −2 V to +2 V between the electrodes in 25 mV per step. The electric currents passing through the dummy cells in the first cycle were recorded as shown in FIG. 1. Obvious amplification to the electric current was observed with the CFE in the presence of iodide anions of gold (“AuI” in the drawings). The cathodic current at +0.5 V attained 28 mA for the CFE whereas it attained only 0.1 mA for the AN-50. Since the apparent diffusion coefficient of the ions is proportional to steady state current (Bard, A. J. and Faulkner, L. R., Electrochemical Methods: Fundamentals and Applications, Chapter 5, page 174, 2nd edition, John Wiley & Sons, Inc., New York, 2001), this is an indication that the CFE has higher apparent diffusion coefficient than the Iodolyte™ AN-50. Thus, the CFE can pass higher electric current through the DSSC than the Iodolyte™ AN-50.

### Example 2

### Effects of a Corrosion-Free Electrolyte of the Present Invention on the Efficiency of DSSCs

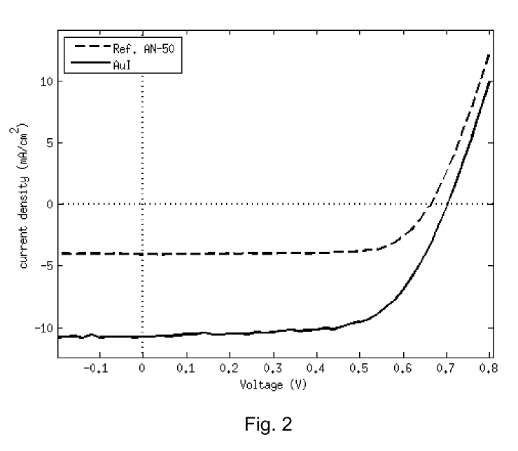

To further demonstrate the effect of CFE in DSSCs, two sets of cells made of transparent conductive oxide glass as the electrodes with the photoanode having a mesoporous TiO₂ layer of TiO₂ nanoparticles were stained with N-719 dye sensitizer and the cells were filled with Iodolyte™ AN-50 and CFE respectively. The CFE used in Example 2 has been prepared as in Example 1, i.e. gold powder has been added to Iodolyte™ AN-50 in an amount of 0.3 wt.-%. The devices were placed under a solar simulator (i.e. Newport Oriel™) fitted with an AM1.5 G filter and an electrical source power meter (i.e. Kiethley 2400™) for measuring the electrical power output from the DSSCs. The typical results with 100 mW/cm² solar irradiation are shown in FIG. 2. The reference cell with Iodolyte™ AN-50 produced short-circuit current density (J_{sc}) of 4.1 mA/cm² and open-circuit voltage (V_{oc}) of 0.62 V, and it attained an overall photovoltaic power conversion efficiency (PCE) of 2.05% and fill factor (FF) of 0.82. On the other hand, the cell with CFE produced J_{sc} of 10.7 mA/cm² and V_{oc} of 0.70 V, and it attained an overall PCE of 4.74% and FF of 0.64. Therefore, the PCE was doubled by replacing the reference electrolyte Iodolyte™ AN-50 by the CFE of the present invention.

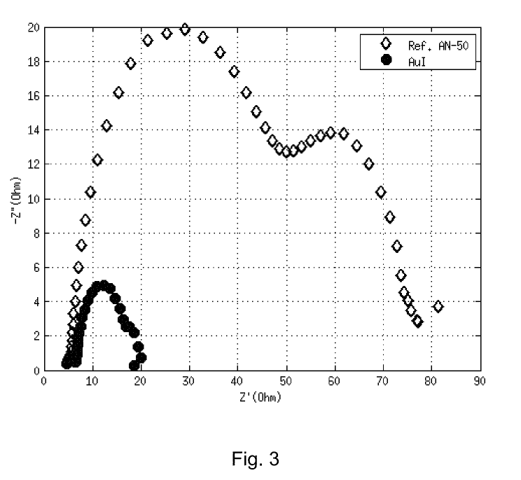

To further analyze the effects of CFE in DSSCs, the same set of cells was tested with electrochemical impedance spectroscopy (EIS) with an electrochemical workstation (i.e. Zahner IM6™) in two-probe configuration. The EIS measurements were performed with bright condition under 100 mW/cm² solar irradiation by the solar simulator. Typical EIS results of the two sets of cells are shown in the Nyquist plots of FIG. 3. The Nyquist plot reveals the impedances of the DSSC (Han, L. et al., Comptes Rendus Chimie, 2006, 9, 645-651), i.e. 1) the real part of the highest frequency impedances of the Nyquist plot at the bottom left of FIG. 3 shows the sheet resistance (Rₕ) of the transparent conductive oxide glass; 2) the diameter of the 1^{st} semi-circle of the Nyquist plot shows the resistance of the counter-electrode (R₁); 3) the diameter of the 2^{nd} semi-circle shows the carrier transport resistance (R₂) of the TiO₂/dye/electrolyte interface; 4) the diameter of the 3^{rd} semi-circle corresponds to the lowest frequency and it shows the diffusion resistance (R₃) of the electrolyte. FIG. 3 shows the change to the resistances of the DSSC by the two electrolytes.

The sheet resistance Rₕ is about 5Ω for both cells since they were made of the same transparent conductive oxide glasses. The resistance of the counter-electrodes R₁ is about 4 for both cells as the counter-electrodes were also made of the same conductive oxide glasses. However, the carrier transport resistance R₂ differs significantly between the reference Iodolyte™ AN-50 and the CFE. The carrier transport resistance R₂ of Iodolyte™ AN-50 attained about 40Ω whereas that of the CFE was merely 10Ω, so the carrier transport resistance at the TiO₂/dye/electrolyte interface of the CFE was reduced substantially to a quarter of the Iodolyte™ AN-50. The diffusion resistance R₃ of the electrolyte was also reduced substantially from 40Ω of the Iodolyte™ AN-50 to about 5Ω of the CFE. The reduction of R₃ in FIG. 3 is in agreement to the result of FIG. 1 which predicts a higher apparent diffusion coefficient of the gold iodide anions (“AuI”) in the CFE. Therefore, it should bring about better electrical charge transport and reduction of the diffusion resistance in the DSSC.

On the other hand, the decrease of R₂ at the TiO₂/dye sensitizer/electrolyte interface may be explained by the reduction of the gold iodide anions from the CFE and the energetic band diagram at the TiO₂/gold interface at the mesoporous photoanode layer. The reduction of gold diiodide anion ([AuI₂]⁻) to metallic gold at the mesoporous TiO₂ photoanode can be expressed by the equilibrium equation Eq. 1,

2Au+I⁻+I₃⁻⇔2[AuI₂]⁻. (Eq. 1)

With the presence of iodine in the electrolyte, the gold iodide(II) anion is oxidized further into gold tetraiodide anion as shown in the equilibrium equation Eq. 2,

[AuI₂]⁻+I₂⇔[AuI₄]⁻. (Eq. 2)

At the counter-electrode, iodine is oxidized by the iodide(I) anion into iodide(III) anion (triiodide anion) as shown in the equilibrium equation Eq. 3,

I₂+I⁻⇔I₃⁻. (Eq. 3)

Combining Eqs. 1, 2 and 3, the overall redox reaction of the corrosion-free electrolyte of the present invention involving gold iodide anions can be expressed as Eq. 4,

3[AuI₂]⁻+2I₂⇔2Au+[AuI₄]⁻+2I₃⁻. (Eq. 4)

Therefore, the elemental gold will be deposited onto the mesoporous TiO₂ photoanode and dissolved back into the iodide/triiodide containing electrolyte at equilibrium. As the iodide/triiodide redox couples were consumed to form gold iodide anions, they can no longer corrode the plasmonic structures embedded in the mesoporous TiO₂ photoanode and, thus, the plasmonic enhancement effect is maintained.

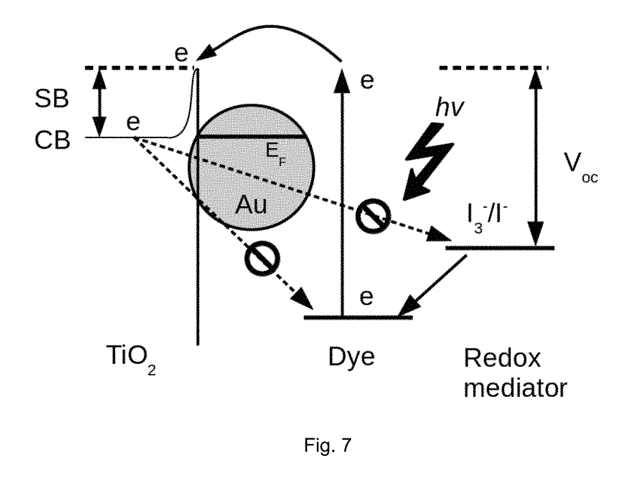

Since the metallic gold element was deposited on the mesoporous TiO₂ surface, a metal-semiconductor heterojunction was formed. As the work function of anatase TiO₂ is about 4.2 eV (Breeze, A. J. et al., Physical Review B, 2001, 64, 125205) whereas that of gold nanoparticle is about 5.35 to 5.76 eV (Khoa, N. T. et al., Applied Catalysis A: General, 2014, 469, 159-164), there is upward bending of the TiO₂ conduction band (CB) and formation of a Schottky barrier (SB). As a result, electrons injected by the dye-sensitizer into the TiO₂ conduction band are retarded from recombination by the SB towards the oxidized dye molecules and the iodide/triiodide redox couple. Such retardation is beneficial to the DSSC because it extends the lifetime of the electron in the CB, thus the photocurrent density increases. The benefit of the SB is supported by the amplification of the short-circuit photocurrent density observed in the CFE cell in comparison to Iodolyte™ AN-50 as shown in FIG. 2. On the other hand, the formation of the SB also increases the conduction band edge of the TiO₂ photoanode. Since the V_{oc} is determined by the difference between the iodide/triiodide redox mediator standard potential and the CB edge of the TiO₂ photoanode, V_{oc} should be enlarged due to the presence of SB. This is indeed observed in FIG. 2 where the V_{oc} of the CFE filled DSSC is larger than that of the Iodolyte™ AN-50 reference. The retardation of electron recombination by the SB and the increased V_{oc} is further illustrated in FIG. 7.

### Example 3

### Optimizing the Concentration of the Gold(I) Iodide Anion in the Corrosion-Free Electrolyte of the Present Invention

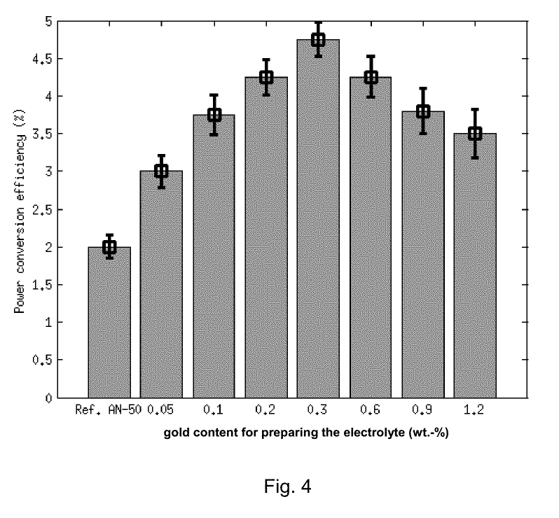

The concentration of the gold(I) iodide anion in the CFE was optimized to achieve the best PCE performance as shown in FIG. 4. The concentration of iodide and triiodide anions were kept fixed in the starting electrolyte solution and 99.99% pure elemental gold powder was added as plasmon-supporting metal containing compound to the pre-mixture of iodide/triiodide ions in acetonitrile. The percentages of gold powder added were 0.05 wt.-%, 0.1 wt.-%, 0.2 wt.-%, 0.3 wt.-%, 0.6 wt.-%, 0.9 wt.-%, and 1.2 wt.-% respectively based on the weight of the electrolyte. Gradual change in the color of the electrolyte from dark brown to light yellowish was observed by the increasing gold weight content. As predicted by Eq. 1, the triiodide that is responsible for the dark brown color was consumed by the gold metal to form gold(I) iodide anion. As the concentration of the triiodide ion dropped, the electrolyte became light yellow of the acetonitrile solvent. However, excessive amount of elemental gold depleted the triiodide ion from the electrolyte as indicated by Eq. 1, so that the iodide/triiodide redox couple ceased to function so that the DSSC performance dropped. The optimal percentage of elemental gold added for the best PCE was found to be 0.3 wt.-%.

In another embodiment, the concentration of the gold(I) iodide anion in the CFE was determined by the weight percentage concentration of the potassium tetraiodoaurate (KAuI₄) added to the pre-mixture of iodide/triiodide ions in acetonitrile. The weight percentage of KAuI₄ was 0.2%, 0.4%, 0.8%, 1.2%, 2.4%, 3.6%, and 4.8% based on the weight of the electrolyte. The optimal percentage of KAuI₄ added for the best PCE was found to be 1.2 wt.-%.

### Example 4

### Effects of Elemental Gold Deposition on the Mesoporous TiO₂ Photoanode from the Corrosion-Free Electrolyte of the Present Invention

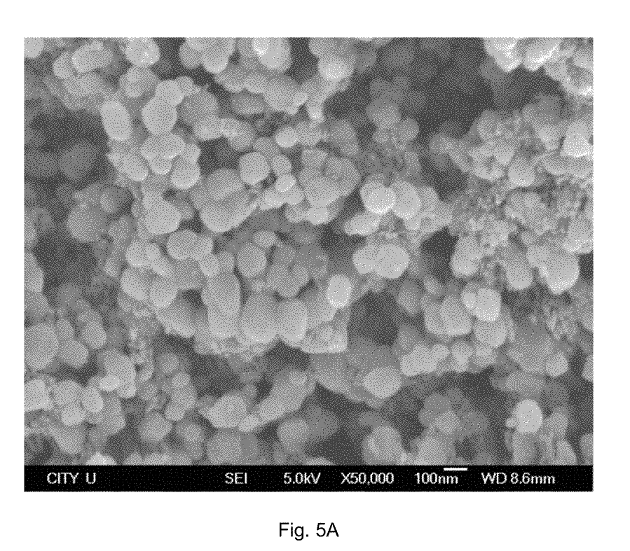

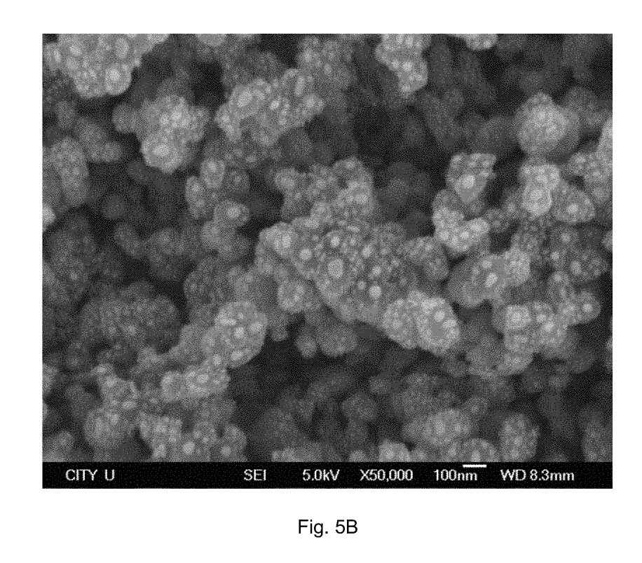

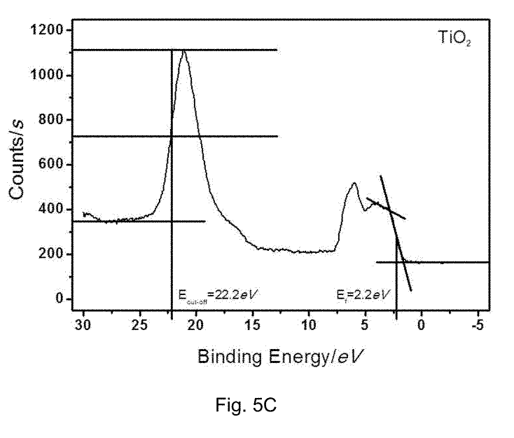

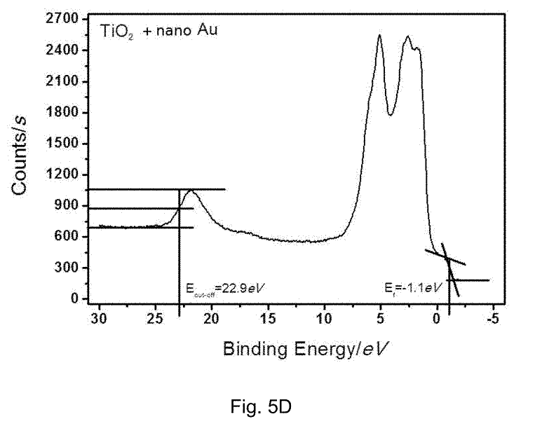

To visualize the results of elemental gold deposition on the mesoporous TiO₂ photoanode, a respective cell with Iodolyte™ AN-50 reference electrolyte and a cell with the CFE prepared in accordance with Example 1 (i.e. gold powder has been added to Iodolyte™ AN-50 in an amount of 0.3 wt.-%) were dissembled after operation. The removed photoanode was soaked in methanol and dried in nitrogen. It was then inspected with a field-emission scanning electron microscope (JOEL JSM-6335F). The cell with reference Iodolyte™ AN-50 electrolyte is shown in FIG. 5A. The image shows that the mesoporous layer with TiO₂ nanoparticles interconnected with one another and the size of the nanoparticles are about 100 nm in diameter. There are also a few clusters of fine grain TiO₂ particles of about 10 nm in diameter. The overall mesoporous TiO₂ layer of FIG. 5A is relatively uniform and clean. However, for the photoanode with CFE as shown in FIG. 5B, there are distinguished gold nanoislands appearing on top of the TiO₂ nanoparticles. The sizes of these nanoislands are about 30 to 60 nm in diameter. The formation of these gold nanoislands agrees with Eq. 1 which predicts the deposition of elemental gold on the photoanode and these elemental gold aggregates to form the nanoislands as shown in FIG. 5B.

To verify the change in work function of the mesoporous anatase TiO₂ layer due to the formation of these nanoislands, X-ray photoelectron spectroscopy (XPS) was performed to measure the work function against the vacuum level for the samples presented in FIG. 5A and FIG. 5B, respectively. The XPS scans of the Iodolyte™ AN-50 and the CFE sample are shown in FIGS. 5C and 5D respectively. Only the energy range relevant to the calculation of the work function is shown. The XPS spectrum of the mesoporous anatase TiO₂ layer is shown in FIG. 5C, and the binding energy covers 30 to −5 eV. XPS experiment with identical configuration was performed with a TiO₂ sample with gold nanoislands of FIG. 5B and it is shown in FIG. 5D. Given the same XPS incident energy hv, the work function is calculated as hv−(E_{cut-off}−E_{f}). As shown in FIG. 5C, (E_{cut-off}−E_{f}) of TiO₂ is determined as 20 eV. In FIG. 5D, (E_{cut-off}−E_{f}) of TiO₂ with gold nanoparticle is determined as 24 eV. Since hv−24 eV must be less than that of hv−20 eV, the work function of the TiO₂ layer modified with gold nanoislands is thus reduced. It implies that the energy difference between the conduction band (CB) edge of the modified TiO₂ layer to the vacuum level is also reduced, so that the CB edge must be banded upwards to form the Schottky barrier (SB) as shown in FIG. 7.

### Example 5

### Standard Electrode Potential of the Corrosion-Free Electrolyte of the Present Invention

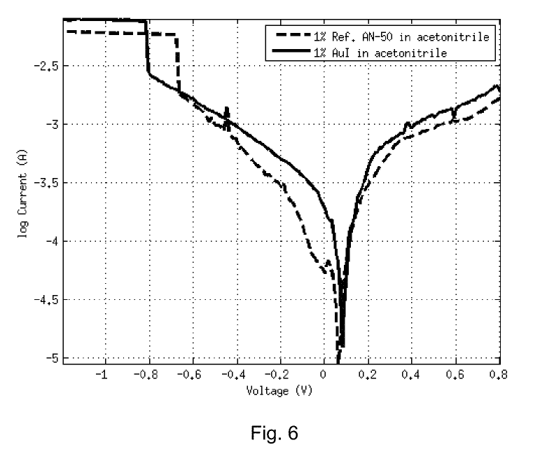

To examine the standard electrode potential of the CFE prepared in accordance with Example 1 (i.e. gold powder has been added to Iodolyte™ AN-50 in an amount of 0.3 wt.-%) and compare it with that of the reference Iodolyte™ AN-50 electrolyte, electrochemical polarization measurements were performed using a chemical workstation (Zahner IM6™) in three-probe configuration. The electrolyte solution was filled into an electrochemical cell with both working electrode and counter-electrode made of platinum (Pt) foil. The reference made of Ag/AgCl (saturated with KCl solution) was immersed and placed as close to the working Pt electrode as possible. The polarization data of the Iodolyte™ AN-50 reference electrolyte and the CFE having gold iodide anions (“AuI”) are shown in FIG. 6. Both electrolytes were diluted by acetonitrile solvent to 1% volume ratio in order to avoid rapid iodide corrosion to the Ag/AgCl reference electrode. The standard electrode potential is located at the point of minimum current through the testing circuit. By observation, the standard electrode potential of both electrolytes is about the same at the 1% concentration. This is an indication that the addition of the plasmon-supporting metal gold into the iodide/triiodide containing electrolyte does not shift the standard electrode potential towards the negative, and a positive standard electrode potential is favorable to the energetics of DSSC for driving the redox reaction forward. In combination of the work function and standard electrode potential data, it can be concluded that the increase in open-circuit voltage of corrosion-free electrolyte is due to the formation of the gold nanoislands by redox reaction at the mesoporous TiO₂ layer.

1. An electrolyte for use in a plasmonic-enhanced dye-sensitized solar cell comprising:
(i) ions of a plasmon-supporting metal for reducing corrosion of plasmonic structures in the plasmonic-enhanced dye-sensitized solar cell;
(ii) a redox couple to donate and accept electrons comprising iodide ions and triiodide ions; and
(iii) an organic solvent.

2. The electrolyte of claim 1, wherein the plasmon-supporting metal is selected from the group consisting of gold, silver, copper, aluminum and mixtures thereof.

3. The electrolyte of claim 1, wherein the ions of the plasmon-supporting metal are selected from gold(I) diiodide anions, gold(III) tetraiodide anions or mixtures thereof.

4. The electrolyte of claim 1, wherein the solvent is selected from the group consisting of acetonitrile, dichloromethane, tetrahydrofuran, ethyl acetate, N,N-dimethylformamide, dimethyl sulfoxide, acetone, hexamethylphosphoric triamide, propylene carbonate and mixtures thereof.

5. The electrolyte of claim 1, wherein the electrolyte is obtained by adding a plasmon-supporting metal containing compound to a pre-mixture comprising the redox couple and the organic solvent.

6. The electrolyte of claim 5, wherein the plasmon-supporting metal containing compound is selected from a plasmon-supporting metal salt, the elemental plasmon-supporting metal or mixtures thereof and the plasmon-supporting metal containing compound is added in an amount of about 0.1 wt.-% to about 10 wt.-% based on the total weight of the electrolyte.

7. The electrolyte of claim 5, wherein the plasmon-supporting metal containing compound is selected from the group consisting of elemental gold, potassium tetraiodoaurate and mixtures thereof.

8. The electrolyte of claim 5, wherein the pre-mixture is obtained by steps comprising adding an organic iodide salt and iodine to the organic solvent.

9. The electrolyte of claim 8, wherein the organic iodide salt is selected from the group consisting of 1,2-dimethyl-3-propylimidazolium iodide, 1-methyl-3-propylimidazolium iodide, 3-hexyl-1-methylimidazolium iodide, 3-hexyl-1,2-dimethylimidazolium iodide, 1-ethyl-3-methylimidazolium iodide, 1,3-dimethylimidazolium iodide, 1-butyl-3-methylimidazolium iodide and mixtures thereof.

10. The electrolyte of claim 8, wherein the organic iodide salt is 1,2-dimethyl-3-propylimidazolium iodide, the organic solvent is acetonitrile, the plasmon-supporting metal containing compound is potassium tetraiodoaurate and the plasmon-supporting metal containing compound, the organic iodide salt, the iodine and the organic solvent are used in the following amounts based on the total weight of the electrolyte:
about 0.2 wt.-% to 4.8 wt.-% potassium tetraiodoaurate;
at least about 50 wt.-% acetonitrile;
about 10 wt.-% to 2 about 5 wt.-% 1,2-dimethyl-3-propylimidazolium iodide; and
about 2.5 wt.-% to about 10 wt.-% iodine.

11. The electrolyte of claim 8, wherein the organic iodide salt is 1,2-dimethyl-3-propylimidazolium iodide, the organic solvent is acetonitrile, the plasmon-supporting metal containing compound is elemental gold and the plasmon-supporting metal containing compound, the organic iodide salt, the iodine and the organic solvent are used in the following amounts based on the total weight of the electrolyte:
about 0.05 wt.-% to about 1.2 wt.-% elemental gold;
at least about 50 wt.-% acetonitrile;
about 10 wt.-% to about 25 wt.-% 1,2-dimethyl-3-propylimidazolium iodide; and
about 2.5 wt.-% to about 10 wt.-% iodine.

12. The electrolyte of claim 8, wherein the plasmon-supporting metal containing compound is selected from the group consisting of a silver(I) iodide, a copper(I) iodide, an aluminum(III) iodide or mixtures thereof and wherein the amount of the plasmon-supporting metal containing compound used is about 0.1 wt.-% to about 10 wt.-% based on the total weight of the electrolyte.

13. A plasmonic-enhanced dye-sensitized solar cell comprising:
a working electrode comprising plasmonic structures for enhancing the electron transfer;
a counter-electrode arranged opposite to the working electrode; and
an electrolyte disposed between the working electrode and the counter-electrode, which electrolyte comprises:
(i) ions of a plasmon-supporting metal for reducing corrosion of the plasmonic structures in the plasmonic-enhanced dye-sensitized solar cell;
(ii) a redox couple to donate and accept electrons comprising iodide ions and triiodide ions; and
(iii) an organic solvent.

14. The plasmonic-enhanced dye-sensitized solar cell of claim 13, wherein the ions of the plasmon-supporting metal are selected from the group consisting of gold(I) diiodide anions, gold(III) tetraiodide anions and mixtures thereof.

15. The plasmonic-enhanced dye-sensitized solar cell of claim 14, wherein the working electrode comprises:
a) a n-type semiconducting material arranged on a transparent conductive substrate;
b) plasmonic structures;
c) a dye sensitizer.

16. The plasmonic-enhanced dye-sensitized solar cell of claim 15, wherein the counter-electrode comprises:
a) a p-type semiconducting material arranged on a transparent conductive substrate;
b) plasmonic structures; and
c) a dye sensitizer.

17. A method of reducing corrosion of plasmonic structures in a plasmonic-enhanced dye-sensitized solar cell comprising:
a) providing an electrolyte comprising:
(i) ions of a plasmon-supporting metal;
(ii) a redox couple comprising iodide ions and triiodide ions; and
(iii) an organic solvent; and
b) disposing said electrolyte between a working electrode and a counter-electrode of the plasmonic-enhanced dye-sensitized solar cell.

18. The method of claim 17, wherein the ions of the plasmon-supporting metal are selected from gold(I) diiodide anions, gold(III) tetraiodide anions or mixtures thereof.

19. A method of improving the efficiency of a dye-sensitized solar cell comprising:
a) providing an electrolyte comprising:
(i) ions of a plasmon-supporting metal;
(ii) a redox couple comprising iodide ions and triiodide ions; and
(iii) an organic solvent; and
b) disposing said electrolyte between a working electrode and a counter-electrode of the dye-sensitized solar cell.

20. The method of claim 19, wherein the ions of the plasmon-supporting metal are selected from gold(I) diiodide anions, gold(III) tetraiodide anions or mixtures thereof.
